(19) United States
(12) Patent Application Publication
(10) Pub. No.: US 2008/0123693 A1
(43) Pub. Date: May 29, 2008

(54) Multiple Flows For Incremental Forward Error Correction Mechanisms

(76) Inventor: Kumar Ramaswamy, Princeton, NJ (US)

Correspondence Address: Joseph J. Laks;Thomson Licensing LLC, 2 Independence Way, Patent Operations, PO Box 5312, PRINCETON, NJ, 08543, US

(21) Appl. No.: 11/791,805

(22) PCT Filed: Jul. 14, 2005
(86) PCT No.: PCT/US05/25025

§ 371 Date: May 29, 2007

Related U.S. Application Data
(60) Provisional application No. 60/633,477, filed on Dec. 6, 2004.

(51) Int. Cl. H04J 3/04; H03M 13/00

(52) U.S. Cl. 370/532; 714/758; 714/E11.007

(57) ABSTRACT

There are provided a customer premise equipment (CPE) device, a corresponding method, and a Digital Subscriber Line Access Multiplexer (DSLAM) for connecting to a digital network and performing forward error correction (FEC). The CPE device includes a decoder for decoding one of a plurality of incremental FEC signals for media content. Each of the plurality of incremental FEC signals is for providing incrementally increasing levels of FEC for the media content.

### CROSS-REFERENCE TO RELATED APPLICATIONS

This application claims the benefit of U.S. Provisional Application Ser. No. 60/633,477, filed Dec. 6, 2004, which is incorporated by reference herein in its entirety.

### FIELD OF THE INVENTION

The present invention relates generally to digital networks and, more particularly, to a method and apparatus for incremental forward error correction in digital networks.

### BACKGROUND OF THE INVENTION

In any digital network, it is possible to apply forward error correction (FEC) at the application layer to improve the robustness of delivered content. This is also true for a digital subscriber line (DSL) network. However, in DSL networks, each drop to the customer premises has a unique behavior in terms of overall end-to-end link quality performance. This variation can be dramatically different. Link layer solutions for each drop solve the problem but not completely. Hence, application layer FEC techniques may be employed to deliver the desired quality suitable for video delivery. Usually, a single FEC stream is generated based on the feedback reports from multiple users. This solution creates an FEC mechanism to cater to the worst-case user.

Accordingly, it would be desirable and highly advantageous to have a method and apparatus for forward error correction in DSL networks that is better tailored to the specific link condition at each drop.

### SUMMARY OF THE INVENTION

These and other drawbacks and disadvantages of the prior art are addressed by the present invention, which is directed to a method and apparatus for incremental forward error correction in digital networks.

According to an aspect of the present invention, there is provided a customer premise equipment (CPE) device for connecting to a digital network and performing forward error correction (FEC). The CPE device includes a decoder for decoding one of a plurality of incremental FEC signals for media content. Each of the plurality of incremental FEC signals is for providing incrementally increasing levels of FEC for the media content.

According to another aspect of the present invention, there is provided a method for performing forward error correction (FEC) in customer premise equipment (CPE) device for connecting to a digital network. The method includes the step of decoding one of a plurality of incremental FEC signals for media content. Each of the plurality of incremental FEC signals is for providing incrementally increasing levels of FEC for the media content.

According to yet another aspect of the present invention, there is provided a Digital Subscriber Line Access Multiplexer (DSLAM) for connecting to a Digital Subscriber Line (DSL) network and performing forward error correction (FEC). The DSLAM includes a selection multiplexer for receiving a plurality of incremental FEC signals for media content, and for selecting one of a plurality of incremental FEC signals to respectively send to each of a plurality of Customer Premise Equipment (CPE) devices connected thereto.

These and other aspects, features and advantages of the present invention will become apparent from the following detailed description of exemplary embodiments, which is to be read in connection with the accompanying drawings.

### BRIEF DESCRIPTION OF THE DRAWINGS

The present invention may be better understood in accordance with the following exemplary figures, in which:

FIG. 1 is a block diagram illustrating an exemplary digital subscriber line (DSL) network in accordance with the principles of the present invention;

FIG. 2 is a flow diagram illustrating an exemplary method for performing forward error correction (FEC) in a customer premise equipment (CPE) device in accordance with the principles of the present invention; and

FIG. 3 is a flow diagram illustrating an exemplary method for performing forward error correction (FEC) in a Digital Subscriber Line Access Multiplexer (DSLAM) in accordance with the principles of the present invention.

### DETAILED DESCRIPTION

The present invention is directed to a method and apparatus for incremental forward error correction (FEC) in digital networks such as, e.g., digital subscriber line (DSL) networks.

Advantageously, the present invention allows for application layer forward error correction to be tailored to the requirements of the specific link condition at each drop. A range of forward error correction flows is maintained to a digital subscriber line access multiplexer (DSLAM) from the point of generation of the content. The flows are separately identifiable and have incremental additions of error correction or parity bytes with respect to each other. A selection of the appropriate FEC level is made at the DSLAM for each drop. The selection of the appropriate set of flows at the DSLAM will result in the application of an appropriate amount of forward error correction for each DSL drop. This improves bandwidth efficiency since the alternative is to use a conservative amount of error correction delivered to all drops. The FEC selection can be driven by the customer premises equipment (CPE) based on measured link quality or it can be implemented by the DSLAM based on information on link quality fed back by the CPE.

It is to be appreciated that while the present invention is primarily described herein with respect to a specific example of a digital network, namely a digital subscriber line (DSL) network, given the teachings of the present invention provided herein, one of ordinary skill in the related art may readily apply the present invention to any digital network wherein, e.g., the characteristics of the individual links from a head end to customer premise equipment (CPE) are varied, while maintaining the scope of the present invention.

The present description illustrates the principles of the present invention. It will thus be appreciated that those skilled in the art will be able to devise various arrangements that, although not explicitly described or shown herein, embody the principles of the invention and are included within its spirit and scope.

All examples and conditional language recited herein are intended for pedagogical purposes to aid the reader in understanding the principles of the invention and the concepts contributed by the inventor to furthering the art, and are to be construed as being without limitation to such specifically recited examples and conditions.

Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that the block diagrams presented herein represent conceptual views of illustrative circuitry embodying the principles of the invention. Similarly, it will be appreciated that any flow charts, flow diagrams, state transition diagrams, pseudocode, and the like represent various processes which may be substantially represented in computer readable media and so executed by a computer or processor, whether or not such computer or processor is explicitly shown.

The functions of the various elements shown in the figures may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (“DSP”) hardware, read-only memory (“ROM”) for storing software, random access memory (“RAM”), and non-volatile storage.

Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

In the claims hereof, any element expressed as a means for performing a specified function is intended to encompass any way of performing that function including, for example, a) a combination of circuit elements that performs that function or b) software in any form, including, therefore, firmware, microcode or the like, combined with appropriate circuitry for executing that software to perform the function. The invention as defined by such claims resides in the fact that the functionalities provided by the various recited means are combined and brought together in the manner which the claims call for. It is thus regarded that any means that can provide those functionalities are equivalent to those shown herein.

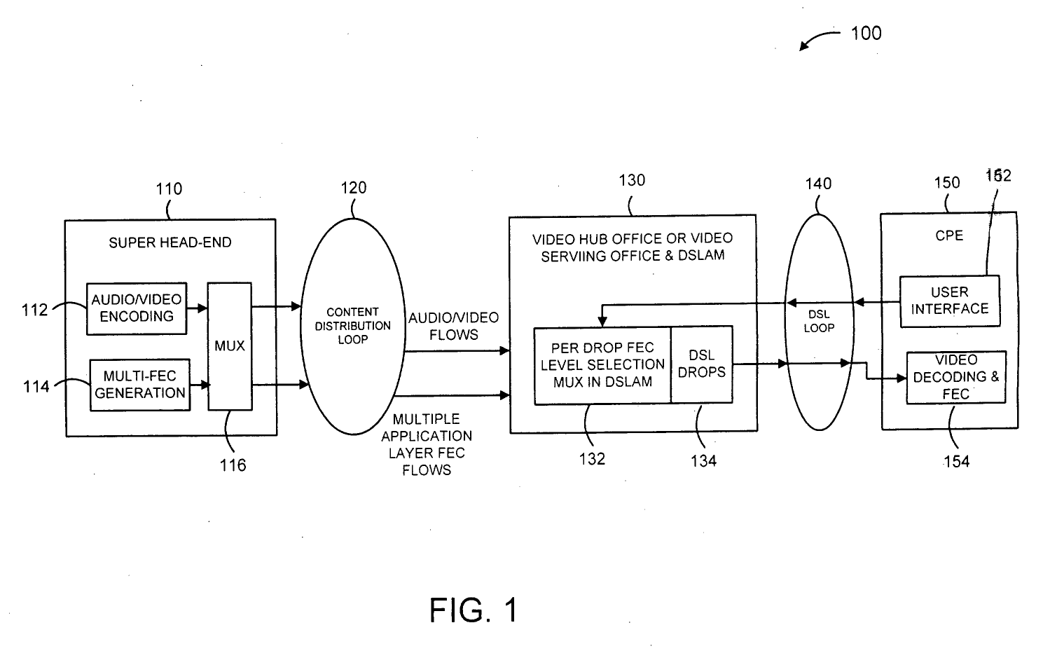

Turning to FIG. 1, an exemplary digital subscriber line (DSL) network is indicated generally by the reference numeral 100. Advantageously, the DSL network 100 is capable of creating, transmitting, and selecting application layer forward error correction (FEC) in accordance with the principles of the present invention.

The DSL network 100 includes a super-head end unit 110, a content distribution center 120, a video hub office or video service office and DSLAM (hereinafter “video hub”) 130, a DSL loop 140, and customer premises equipment (CPE) 150.

The super-head end unit 110 includes an audio/video encoder 112, a multi-FEC generation module 114, and a multiplexer (also referred to here as “mux” for short) 116. An output of the audio/video encoder 112 is connected in signal communication with a first input of the multiplexer 116. An output of the multi-FEC generation module 114 is connected in signal communication with a second input of the multiplexer 116. A first output of the multiplexer 116 is connected in signal communication with a first input of the content distribution center 120. A second output of the multiplexer 116 is connected in signal communication with a second input of the content distribution center 120.

The video hub 130 includes a selection multiplexer 132. The selection multiplexer 132 has a first input (for audio/video flows) in signal communication with a first output of the content distribution center 120 and a second input (for multiple application layer FEC flows) in signal communication with a second output of the content distribution center 120. The selection multiplexer 132 has a third input in signal communication with an output of the DSL loop 140.

An output of the video hub 130, corresponding to one of a plurality of DSL drops, is connected in signal communication with a video decoder with FEC capability included in the customer premise equipment 150. The customer premise equipment also includes a user interface having an output in signal communication with an input of the DSL loop 140.

FIG. 1 also illustrates the creation, transmission and selection of application layer FEC. In DSL network 100, an incremental FEC mechanism (such as, but not limited to, block parity Reed-Solomon codes or Tornado codes) is generated at the application layer at the source of content generation (or the server). Separate flows for several incremental parity bytes are maintained until the DSLAM 130. At the DSLAM 130, a selection is made (driven either by the CPE 150 based on its judgment of link quality or by the DSLAM 130 based on reports of link quality by the CPE 150) on the appropriate FEC flows to be selected to guarantee a reliable link to the CPE 150. For example, let us consider a RS code based on a 255 byte alphabet. Let us further presume that the maximum number of parity bytes is 128. This implies that we can have a 128/255 rate code for a really bad channel or a more traditional 238/255 rate code (with 16 parity bytes capable of detecting and correcting 8 bytes or capable of correcting 16 bytes if based on erasures) for a good channel or no application layer FEC at all for a really clean channel. Each parity byte or group of parity bytes can be maintained as separate flows from the content source to the DSLAM 130. Since the chosen codes are incremental, e.g., each additional pair of parity bytes will incrementally assist in detecting and correcting one additional error, it will be possible to concatenate the appropriate groups of parity bytes from separate flows to achieve stronger error protection. The appropriate level of error correction code is selected either by the CPE 150 or by the DSLAM 130 as indicated earlier. The cost of this solution is the carriage of the worst case FEC overhead through the backbone until the DSLAM 130. However, since only the right amount of FEC bytes are sent to each CPE 150, the segment of the DSL network (namely, the bandwidth between the DSLAM 130 and the CPE 150, as represented by the DSLP loop 140) with the bandwidth bottleneck is permitted to run most efficiently to deliver the necessary link quality.

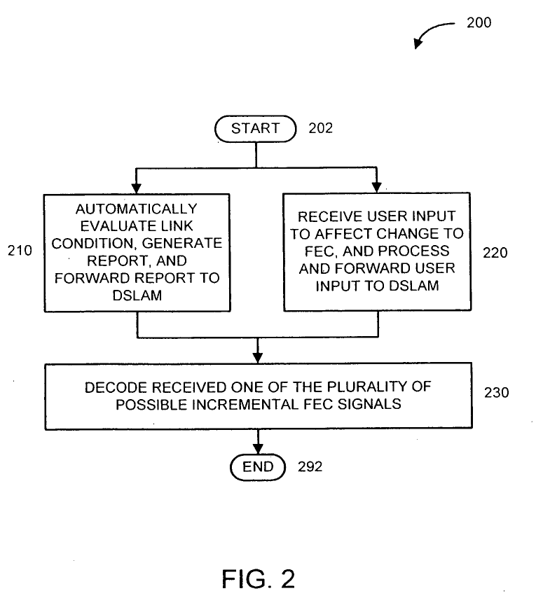

Turning to FIG. 2, an exemplary method for performing forward error correction (FEC) in a customer premise equipment (CPE) device is indicated generally by the reference numeral 200. The CPE device 200 is for connecting to a Digital Subscriber Line (DSL) network.

A start block 202 passes control to any one of a function block 210 and a. function block 220. The function block 210 automatically evaluates the link condition of the drop corresponding to the CPE device, generates a report about the link condition, forwards the report to another device in the DSL network (e.g., the DSLAM 130, which in this example includes the selection multiplexer 132), and passes control to a function block 230.

The function block 220 receives a user input to affect a change to the FEC amount, processes and forwards the user input (e.g., to the DSLAM 130), and passes control to function block 230. The function block 230 decodes the received one of the plurality of possible incremental FEC signals, and passes control to an end block 292. Accordingly, the received incremental FEC signal is tailored to the particular link condition for the corresponding drop.

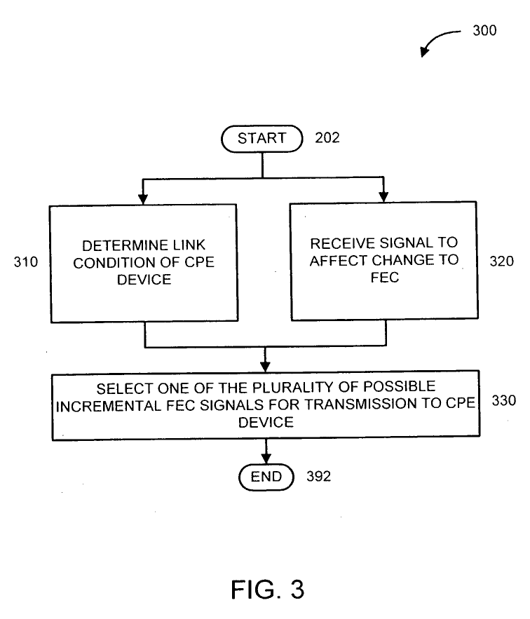

Turning to FIG. 3, an exemplary method for performing forward error correction (FEC) in a Digital Subscriber Line Access Multiplexer (DSLAM) is indicated generally by the reference numeral 300. The DSLAM 300 is for connecting to a Digital Subscriber Line (DSL) network.

A start block 302 passes control to any one of a function block 310 and a function block 320. The function block 310 determines the link condition(s) of the drop(s) corresponding to the CPE device(s), and passes control to a function block 330.

The function block 320 receives a signal (e.g., indicative of link condition) to affect a change to the FEC amount, and passes control to function block 330. The function block 330 selects one of the plurality of possible incremental FEC signals, e.g., based upon the link condition determined by function block 310 and/or the signal received by function block 320, and passes control to an end block 392. Accordingly, the transmitted incremental FEC signal is tailored to the particular link condition for the corresponding drop.

These and other features and advantages of the present invention may be readily ascertained by one of ordinary skill in the pertinent art based on the teachings herein. It is to be understood that the teachings of the present invention may be implemented in various forms of hardware, software, firmware, special purpose processors, or combinations thereof.

Most preferably, the teachings of the present invention are implemented as a combination of hardware and software. Moreover, the software is preferably implemented as an application program tangibly embodied on a program storage unit. The application program may be uploaded to, and executed by, a machine comprising any suitable architecture. Preferably, the machine is implemented on a computer platform having hardware such as one or more central processing units (“CPU”), a random access memory (“RAM”), and input/output (“I/O”) interfaces. The computer platform may also include an operating system and microinstruction code. The various processes and functions described herein may be either part of the microinstruction code or part of the application program, or any combination thereof, which may be executed by a CPU. In addition, various other peripheral units may be connected to the computer platform such as an additional data storage unit and a printing unit.

It is to be further understood that, because some of the constituent system components and methods depicted in the accompanying drawings are preferably implemented in software, the actual connections between the system components or the process function blocks may differ depending upon the manner in which the present invention is programmed. Given the teachings herein, one of ordinary skill in the pertinent art will be able to contemplate these and similar implementations or configurations of the present invention.

Although the illustrative embodiments have been described herein with reference to the accompanying drawings, it is to be understood that the present invention is not limited to those precise embodiments, and that various changes and modifications may be effected therein by one of ordinary skill in the pertinent art without departing from the scope or spirit of the present invention. All such changes and modifications are intended to be included within the scope of the present invention as set forth in the appended claims.

What is claimed is:

1. A customer premise equipment (CPE) device for connecting to a digital network and performing forward error correction (FEC), the CPE device comprising:
a decoder for decoding one of a plurality of incremental FEC signals for a media content, each of the plurality of incremental FEC signals for providing incrementally increasing levels of FEC for the media content.

2. The CPE device according to claim 1, wherein the decoded one of the plurality of incremental FEC signals is received by said decoder in response to a signal sent by the CPE relating to link quality.

3. The CPE device according to claim 1, wherein the digital network is a digital subscriber line (DSL) network.

4. The CPE device according to claim 3, wherein the DSL network includes a Digital Subscriber Line Access Multiplexer (DSLAM) for selecting which of the plurality of incremental FEC signals is transmitted to the CPE device, and the CPE device further comprises an FEC control device for generating a signal for transmission to the DSLAM to affect the selection by the DSLAM.

5. The CPE device according to claim 4, wherein the FEC control device comprises a user interface for receiving a user input to affect the selection by the DSLAM.

6. The CPE device according to claim 5, wherein the user input specifies a user perceived quality of the link condition.

7. The CPE device according to claim 4, wherein the FEC control device comprises:
a link condition evaluation circuit for evaluating the link condition at the corresponding drop; and
a report generator for generating a report for transmission to the DSLAM based on a result of the link condition evaluation.

8. The CPE device according to claim 1, wherein the plurality of incremental FEC signals are configured to enable concatenation of corresponding groups of parity blocks from separate ones of the plurality of incremental FEC signals to increase error protection.

9. A method for performing forward error correction (FEC) in customer premise equipment (CPE) device for connecting to a digital network, the method comprising the step of decoding one of a plurality of incremental FEC signals for a media content, each of the plurality of incremental FEC signals for providing incrementally increasing levels of FEC for the media content.

10. The method according to claim 9, further comprising the step of receiving the decoded one of the plurality of incremental FEC signals in response to a signal sent by the CPE relating to link quality.

11. The method according to claim 9, wherein the digital network is a Digital Subscriber Line (DSL).

12. The method according to claim 11, wherein the DSL network includes a Digital Subscriber Line Access Multiplexer (DSLAM) for selecting which of the plurality of incremental FEC signals is transmitted to the CPE device, and the method further comprises the step of generating a signal for transmission to the DSLAM to affect the selection by the DSLAM.

13. The method according to claim 12, wherein said generating step comprises the step of receiving a user input to affect the selection by the DSLAM.

14. The method according to claim 13, wherein the user input specifies a user perceived quality of the link condition.

15. The method according to claim 12, wherein said generating step comprises the steps of:
evaluating the link condition at the corresponding drop; and
generating a report for transmission to the DSLAM based on a result of the link condition evaluation.

16. The method according to claim 9, wherein the plurality of incremental FEC signals are configured to enable concatenation of corresponding groups of parity blocks from separate ones of the plurality of incremental FEC signals to increase error protection.

17. A Digital Subscriber Line Access Multiplexer (DSLAM) for connecting to a Digital Subscriber Line (DSL) network and performing forward error correction (FEC), the DSLAM comprising:
a selection multiplexer for receiving a plurality of incremental FEC signals for a media content, and for selecting one of a plurality of incremental FEC signals to respectively send to each of a plurality of Customer Premise Equipment (CPE) devices connected thereto.

18. The DSLAM according to claim 17, wherein the selection multiplexer selects the one of the plurality of incremental FEC signals to respectively send to the plurality of CPE devices in response to respective signals received from the plurality of CPE devices, the respective signals relating to a link quality of a corresponding one of a plurality of drops.

19. The DSLAM according to claim 17, wherein the plurality of incremental FEC signals are configured to enable concatenation of corresponding groups of parity blocks from separate ones of the plurality of incremental FEC signals to increase error protection.

20. The DSLAM cording to claim 17, wherein each of the plurality of incremental FEC signals is selected based on a link condition at a respective DSL drop.
